(19) United States
(12) Patent Application Publication
(10) Pub. No.: US 2014/0187058 A1
(43) Pub. Date: Jul. 3, 2014

(54) Modular Multiple Piece Socket For Enhanced Thermal Management

(71) Applicants: Hongfei Yan, Mesa, AZ (US); Jeffory L. Smalley, East Olympia, WA (US)

(72) Inventors: Hongfei Yan, Mesa, AZ (US); Jeffory L. Smalley, East Olympia, WA (US)

(21) Appl. No.: 13/728,735

(22) Filed: Dec. 27, 2012

(51) Int. Cl. H01R 13/502; H05K 7/20; H01R 12/51

(52) U.S. Cl. CPC H01R 13/502; H01R 12/51; H05K 7/20436
USPC 439/55; 439/485; 439/701

(57) ABSTRACT

A modular multiple piece socket and a computing system are described herein. The modular multiple piece socket includes a plurality of socket pieces, wherein at least one corridor separates the socket pieces. The plurality of socket pieces may be configured to secure a processing unit to a printed circuit board. The at least one corridor may be filled with a thermally conductive material.

### TECHNICAL FIELD

The present invention relates generally to sockets of a printed circuit board. More specifically, the present invention relates to multiple piece sockets with corridors for placement of thermally conductive material, trace routing, and power planes.

### BACKGROUND ART

A socket is a connector on the motherboard provides mechanical and electrical connections between a component that is placed in the socket and the printed circuit board (PCB). Pins on the underside of the component are inserted in holes within the socket. Each hole of the socket is traced to various connections on the PCB. The PCB typically includes multiple layers, with the top layer configured to mounting the socket and other electrical components. Central processing units (CPUs) are typically inserted into sockets in order to connect to the PCB. The multiple layers of the PCB include signal traces that connect the electrical components mounted on the PCB. Additional layers of the PCB may provide power and ground connections to the electrical components.

### BRIEF DESCRIPTION OF THE DRAWINGS

FIG. 1A is a diagram of a two piece socket, in accordance with embodiments;

FIG. 1B is a diagram of a four piece socket, in accordance with embodiments;

FIG. 2 is a diagram of a four piece socket with thermally conductive material, in accordance with embodiments;

FIG. 3 is a diagram of a multiple piece socket with thermally conductive material, CPU, and CPU heat sink, in accordance with embodiments; and

FIG. 4 is a block diagram of a computing device that may be used in accordance with embodiments.

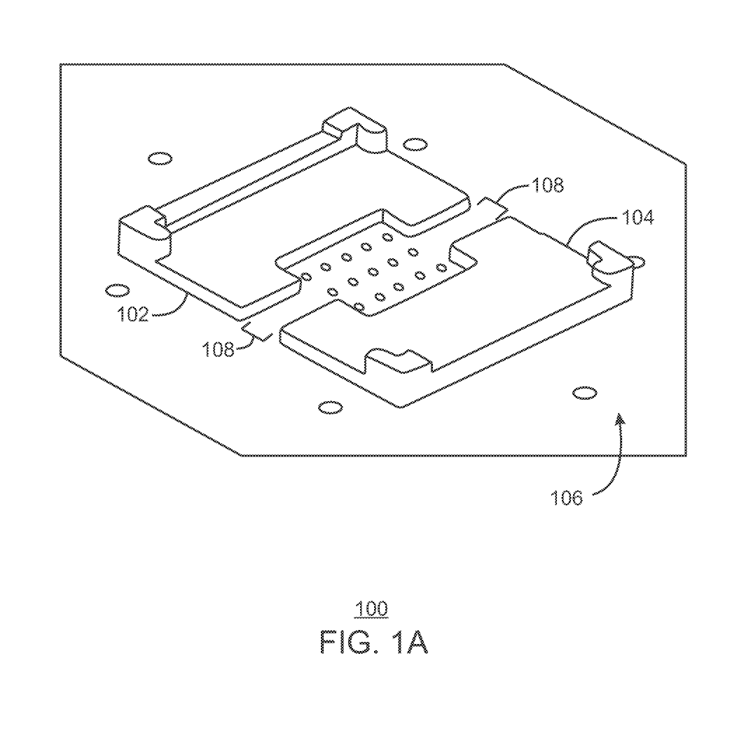

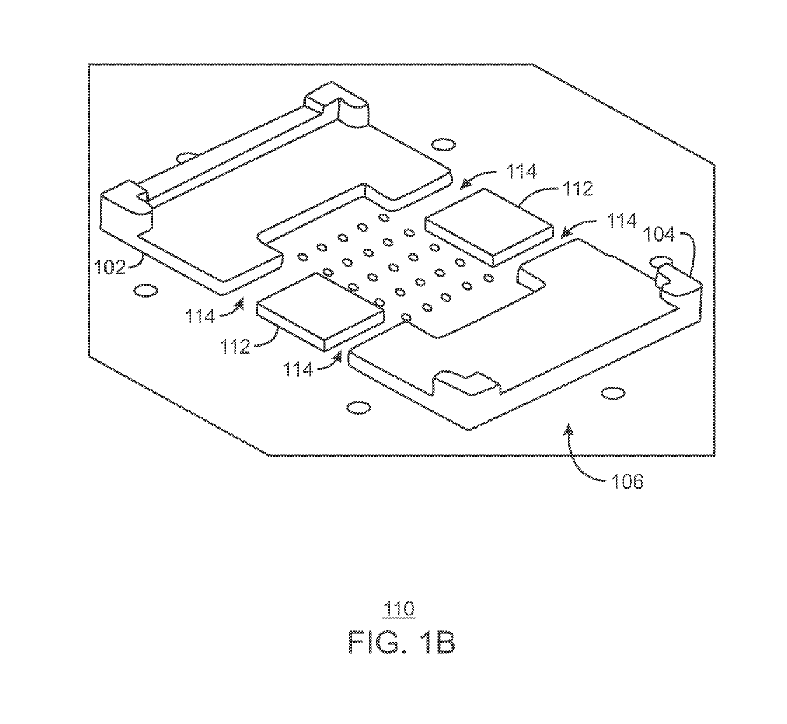

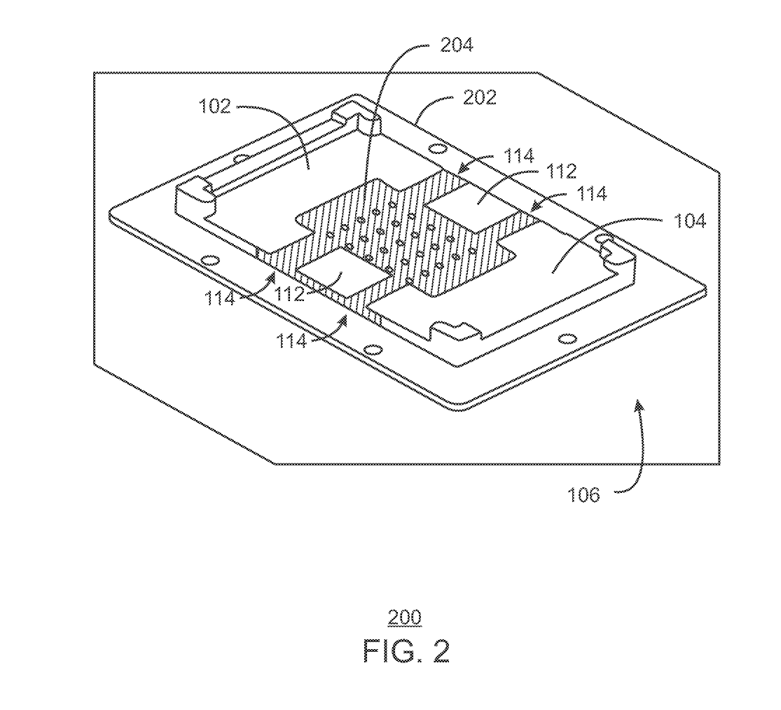

The same numbers are used throughout the disclosure and the figures to reference like components and features. Numbers in the 100 series refer to features originally found in FIG. 1; numbers in the 200 series refer to features originally found in FIG. 2; and so on.

### DESCRIPTION OF THE EMBODIMENTS

As discussed above, CPUs typically use sockets to connect to the PCB. As CPUs increase in complexity, the package size of the CPU becomes larger, along with an increased socket pin count there is typically an increase in thermal demands on the processor heat sink. To maintain cost competitiveness, the socket pin pitch has shrunk with each new generation of processors in order to minimize the influence of the increased pin count demand on the overall package size. Pin pitch refers to the minimum distance allowed between each pin of the CPU package. This pitch shrink, in conjunction with pin count demand increases, is constrained by signal routing breakout depth limitations on the PCB. The PCB layer count has been increased to accommodate the increase in pin count demands. However, this results in an increase in the overall cost of the computing system. In addition to increased demand on trace routing, increases in the CPU size and complexity comes with increased thermal demand from the CPU package.

For example, Fully Integrated Voltage Regulator (FIVR) technology involves placement of air core inductors internal to the package substrate. A FIVR generates heat as part of the normal operation, resulting in localized internal package substrate self-heating. This heat must be removed by the CPU heat sink as the heat will result in higher junction temperatures for the die. This internal self-heating also leads to higher package landside temperatures providing a negative impact on any CPU surface mount components such as decoupling capacitors that that reside in the socket cavity. As used herein, landside temperatures refer to the temperatures on the surface of the CPU substrate. Since the socket cavity is fully enclosed in sockets, there are no thermal management techniques employed to directly influence landside package components.

Additionally, the reduction in socket pin pitch can cause an increase in system power loss due to increases in the power path resistance (R-path) of the PCB and CPU package. For example, power for the CPU is typically routed from the voltage regulators at a different location on the PCB to the socket pin field using solid planes of copper in the board build up layers to minimize the R-path in the PCB. The power is then transferred to the package through the socket using a consolidated grouping of socket contacts. These power planes and grouping of socket contacts are typically referred to as the power corridor. Typically, the wider the power corridor, then the lower the R-path. This results in a lower power loss within the system. However, as discussed above, as I/O counts increase there is increasing pressure to narrow the power corridor which is already impacted by the shrinking socket pin pitch. To counteract the narrower power corridor additional socket pins are repurposed as power contacts and additional power planes are added to the package substrate. Additional power planes come at a cost of additional layers in the system PCB, while the additional contacts that are provided are typically around the socket cavity where they provide some marginal but not efficient relief to the R-path issue.

Accordingly, embodiments described herein provide a multiple piece socket. The multiple piece socket enables thermal management techniques for landside components within the socket. Moreover, the multiple piece socket enables various signal breakout configurations. And lower R-path to power pins located near the socket cavity.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

Some embodiments may be implemented in one or a combination of hardware, firmware, and software. Some embodiments may also be implemented as instructions stored on a machine-readable medium, which may be read and executed by a computing platform to perform the operations described herein. A machine-readable medium may include any mechanism for storing or transmitting information in a form readable by a machine, e.g., a computer. For example, a machine-readable medium may include read only memory (ROM); random access memory (RAM); magnetic disk storage media; optical storage media; flash memory devices; or electrical, optical, acoustical or other form of propagated signals, e.g., carrier waves, infrared signals, digital signals, or the interfaces that transmit and/or receive signals, among others.

An embodiment is an implementation or example. Reference in the specification to “an embodiment,” “one embodiment,” “some embodiments,” “various embodiments,” or “other embodiments” means that a particular feature, structure, or characteristic described in connection with the embodiments is included in at least some embodiments, but not necessarily all embodiments, of the inventions. The various appearances of “an embodiment,” “one embodiment,” or “some embodiments” are not necessarily all referring to the same embodiments. Elements or aspects from an embodiment can be combined with elements or aspects of another embodiment.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

It is to be noted that, although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

FIG. 1A is a diagram of a two piece socket 100, in accordance with embodiments. The socket may be used to provide electrical connections from a processing unit or integrated circuit package to a printed circuit board. The multiple piece socket 100 includes a socket piece 102 and a socket piece 104 that are secured atop of a PCB 106. Between the socket piece 102 and the socket piece 104, there is a corridor 108 that is formed by the two socket pieces 102 and 104. The corridor 108 is a space on the surface of the PCB 106 where no socket connections occur.

Typically, a socket of plastic and includes a latch that is used to secure the CPU to the socket. The socket also includes contacts for each of the pins or lands on the CPU. The contacts are typically made of metal. The pins or lands of the CPU are in contact with the contacts of the socket that are routed to signal traces on the PCB. The signal traces of the PCB may be positioned between the contacts of the socket piece 102 and the socket piece 104. The positioning of the signal traces of the multi-layer PCB are limited by the number of layers of the PCB, as well as the predetermined minimum pitch between traces and pitch of the socket contacts. The pitch between traces specifies a minimum distance of separation between the signal traces in order to ensure proper operation of the signal traces.

In embodiments, the addition of the corridor 108 enables a higher number of signal traces to be routed from the socket to the PCB when compared to a socket without a corridor 108. Moreover, in embodiments, the PCB includes traces for power and ground signals, which may be larger than other signal traces of the PCB. A layer of the PCB may be a solid metal in order to act as a ground or power plane. In embodiments, the solid metal is copper. The power plane may behave a signal ground for an alternating current (AC) signal, while also providing direct current (DC) voltage for powering electrical components mounted on the PCB, such as the CPU mounted in the multiple piece socket 100. In embodiments, a power plane of the PCB may be routed directly underneath the corridor 108. In this manner, cross-talk and impedance mismatches between the signals may be reduced.

The electrical performance of the traces are affected by a number of factors, such as the jogs (the number of bends to weave through the pattern), the length of the traces, the number of traces moving between particular circuit connection points, and the proximity of traces to each other. Using the multiple piece socket, the increased area on the surface of the PCB 106 may enable electrical performance of the traces to be improved. Specifically, the uniformity of the jogs and the sharpness of jogs for each signal trace may be improved.

FIG. 1B is a diagram of a four piece socket 110, in accordance with embodiments. The multiple piece socket 110 includes a socket piece 102 and a socket piece 104 that are secured atop of a PCB 106. Additionally, the socket piece 102 and the socket piece 104 are separated by a socket piece 112 at each end. Accordingly, the socket pieces 102, the socket piece 104, and the two socket pieces 112 form four corridors 114 on the surface of the PCB 106.

Through the additional corridors 114, the four piece socket 110 enables a higher number of signal traces to be routed from the socket to the PCB when compared to the two piece multiple piece socket 100 (FIG. 1 A). Similar to FIG. 1A, a power plane of the PCB may be routed directly underneath the corridors 114. In this manner, cross-talk and impedance mismatches between the signals may be reduced. Additionally, the electrical performance of the traces routed from the four piece socket 110 may also be improved by increasing the uniformity of the jogs and the sharpness of jogs for each signal trace. Accordingly, the corridors can be used for signal I/O breakouts from inner pin field of the multiple piece socket, which allows deeper pin field depth. Surface electrical components on motherboard and on CPU package can also be placed on these corridors when needed and when socket cavity space is constraint.

In embodiments, compressible thermally conductive materials may be placed in the corridors between the socket pieces, thereby enabling thermal contact to package landside surface components. The thermally conductive material may conduct heat away from the CPU to a metal frame of loading mechanism. The loading mechanism includes the lever used to secure the CPU to the socket, as discussed above. The corridors may also enable direct power delivery paths from PCB voltage regulator to the socket pins around an inter-socket cavity that is under the “shadow” of the CPU. Such a placement of the power delivery paths from PCB voltage regulator to the socket pins around the inter-socket cavity can reduces the system R-path.

FIG. 2 is a diagram of a four piece socket 200 with thermally conductive material, in accordance with embodiments. Although a four piece socket is used, any multiple piece socket may be used, including but not limited to the two piece multiple socket described above. The four piece socket 200 includes a load mechanism frame 202. The lever used to secure the CPU to the PCB may be a component of the load mechanism frame 202. Additionally, a thermally conductive material 204 has been placed between the pieces of the multiple piece socket. Specifically, the thermally conductive material 204 may be placed in the corridors 114 atop the PCB 106 and between the socket piece 102, the socket piece 104, and the two socket pieces 112. In embodiments, the thermally conductive material 202 extends underneath the load mechanism frame 202. Moreover, in embodiments, the thermally conductive material 204 may be compressible thermal tape, thermal grease, phase change material, or the like.

Through the multiple piece socket, a lateral heat transfer is enabled for landside components, while the space on board layers of the PCB may be used for un-interrupted power planes or signal breakouts as described above. Moreover, the thermally conductive material placed in corridors between the modular socket pieces thermally connects the package landside cavity and the outside socket loading mechanism metal frame for heat dissipation.

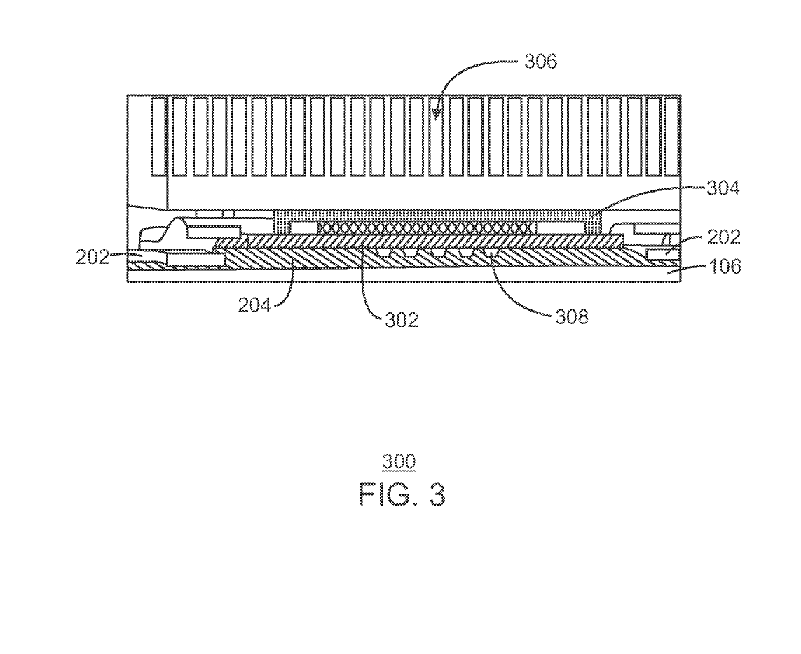

FIG. 3 is a diagram of a multiple piece socket 300 with thermally conductive material, CPU, and CPU heat sink, in accordance with embodiments. Any multiple piece socket may be used, including but not limited to the two piece multiple socket or the four piece socket described above. The multiple piece socket 300 illustrates a CPU 302 with an integrated heat spreader 304. The integrated heat spreader 304 may also be in contact with a CPU heat sink 306. The heat spreader 304 and the CPU heat sink 306 may be any type of heat sink now in use or developed in the future, such as a pin type heat sink. The CPU 302 may also be coupled with one or more landside capacitors 308. The landside capacitors may be used to reduce system noise and unwanted signals in the CPU 302.

The thermally conductive material 204 provides an additional path to carry heat away from the CPU 302. Specifically, the thermally conductive material 204 may carry heat laterally from the processor 302, rather than the upward path through the heat spreader 304 and the CPU heat sink 306. In embodiments, fans and other devices may be used alongside the thermally conductive material 204 in order to maintain suitable operating temperatures for the processor 302.

The multiple piece socket enables a reduction in manufacturing costs by enabling identical pieces of the socket to be configured for different processing units. For example, the two piece socket 100 may be configured for a smaller processing unit (FIG. 1A). Through the addition of socket pieces 112, the four piece socket 110 may be configured for a larger, more powerful processor when compared to that for the two piece socket.

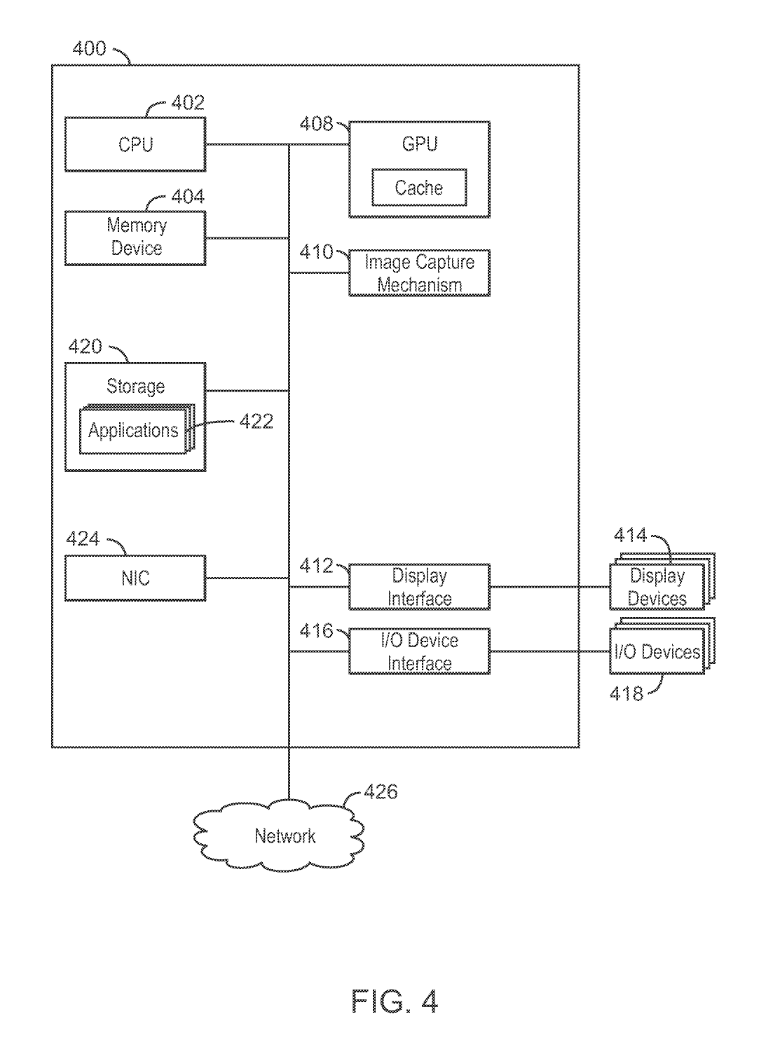

FIG. 4 is a block diagram of a computing device 400 that may be used in accordance with embodiments. The computing device 400 may be, for example, a laptop computer, desktop computer, tablet computer, mobile device, or server, among others. The computing device 400 may include a central processing unit (CPU) 402 that is configured to execute stored instructions, as well as a memory device 404 that stores instructions that are executable by the CPU 402. The CPU may be coupled to the memory device 404 by a bus 406. Additionally, the CPU 402 can be a single core processor, a multi-core processor, a computing cluster, or any number of other configurations. Furthermore, the computing device 400 may include more than one CPU 402. The instructions that are executed by the CPU 402 may be used to combine print jobs in accordance with embodiments.

The computing device 400 may also include a graphics processing unit (GPU) 408. As shown, the CPU 402 may be coupled through the bus 406 to the GPU 408. The GPU 408 may be configured to perform any number of graphics operations within the computing device 400. For example, the GPU 408 may be configured to render or manipulate graphics images, graphics frames, videos, or the like, to be displayed to a user of the computing device 400. In some embodiments, the GPU 408 includes a number of graphics engines, wherein each graphics engine is configured to perform specific graphics tasks, or to execute specific types of workloads. In embodiments, the method for combining print jobs described herein is performed by at least one of the CPU, the GPU, or any combination thereof.

The memory device 404 can include random access memory (RAM), read only memory (ROM), flash memory, or any other suitable memory systems. For example, the memory device 404 may include dynamic random access memory (DRAM). The memory device 404 may include drivers 410 that are configured to execute the instructions for combining print jobs. The driver 410 may be software, an application program, application code, or the like.

The computing device 400 includes an image capture mechanism 412. In embodiments, the image capture mechanism 412 is a camera, stereoscopic camera, scanner, infrared sensor, or the like. The image capture mechanism 412 is used to capture image information. The image capture mechanism may employ various sensors to capture image information, such as an image sensor, a charge-coupled device (CCD) image sensor, a complementary metal-oxide-semiconductor (CMOS) image sensor, a system on chip (SOC) image sensor, an image sensor with photosensitive thin film transistors, or any combination thereof. In embodiments, the driver 410 may combine an image from the image capture mechanism 412 with a print job that has been previously printed.

The CPU 402 may be linked through the bus 406 to a display interface 414 configured to connect the computing device 400 to a display device 416. The display device 416 may include a display screen that is a built-in component of the computing device 400. The display device 416 may also include a computer monitor, television, or projector, among others, that is externally connected to the computing device 400.

The CPU 402 may also be connected through the bus 406 to an input/output (I/O) device interface 418 configured to connect the computing device 400 to one or more I/O devices 420. The I/O devices 420 may include, for example, a keyboard and a pointing device, wherein the pointing device may include a touchpad or a touchscreen, among others. The I/O devices 420 may be built-in components of the computing device 400, or may be devices that are externally connected to the computing device 400.

The computing device also includes a storage device 422. The storage device 422 is a physical memory such as a hard drive, an optical drive, a thumbdrive, an array of drives, or any combinations thereof. The storage device 422 may also include remote storage drives. The storage device 422 includes any number of applications 424 that are configured to run on the computing device 400. The applications 424 may be used to combine the print jobs.

The computing device 400 may also include a network interface controller (NIC) 426 may be configured to connect the computing device 400 through the bus 406 to a network 428. The network 428 may be a wide area network (WAN), local area network (LAN), or the Internet, among others.

The block diagram of FIG. 4 is not intended to indicate that the computing device 400 is to include all of the components shown in FIG. 4. Further, the computing device 400 may include any number of additional components not shown in FIG. 4, depending on the details of the specific implementation.

### EXAMPLE 1

A multiple piece socket is described herein. The multiple piece socket includes a plurality of socket pieces, wherein at least one corridor separates the socket pieces. The plurality of socket pieces may be configured to secure a processing unit to a printed circuit board. The at least one corridor may be filled with a thermally conductive material. Additionally, the multiple piece socket may include a load mechanism frame. A power plane may be located within a layer of a printed circuit board beneath the at least one corridor. The at least one corridor may increases a number of signal traces from the multiple piece socket. Additionally, the at least one corridor may decrease an R-path for a computing device including the multiple piece socket.

### EXAMPLE 2

A socket for an integrated circuit package is described herein. The socket includes a plurality of socket pieces, wherein at least one channel separates the socket pieces. The plurality of socket pieces may be configured to secure the integrated circuit package to a printed circuit board. The at least one channel may be filled with a thermally conductive material that is in contact with the integrated circuit package. Additionally, the socket may include a load mechanism frame with a lever for securing the integrated circuit package within the socket. A power plane may be located within a layer of a printed circuit board beneath the at least one channel. At least one channel may increase a number of signal traces from the multiple piece socket. The at least one channel may also decrease an R-path for a computing device including the multiple piece socket. Further, the integrated circuit package is coupled with at least one heat sink.

### EXAMPLE 3

A system is described herein. The system includes a host computing system, a printed circuit board coupled to the host computing system, and a multiple piece socket coupled to the printed circuit board, wherein the multiple piece socket includes a plurality of socket pieces and at least one corridor, wherein the at least one corridor separates the socket pieces. The plurality of socket pieces may be configured to secure a processing unit to a printed circuit board. Additionally, the at least one corridor may be filled with a thermally conductive material. The at least one corridor may decrease an R-path for the system including the multiple piece socket. Further, the multiple piece socket may include a load mechanism frame.

It is to be understood that specifics in the aforementioned examples may be used anywhere in one or more embodiments. For instance, all optional features of the computing device described above may also be implemented with respect to either of the methods or the computer-readable medium described herein. Furthermore, although flow diagrams and/or state diagrams may have been used herein to describe embodiments, the inventions are not limited to those diagrams or to corresponding descriptions herein. For example, flow need not move through each illustrated box or state or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

What is claimed is:

1. A multiple piece socket, comprising:
a plurality of socket pieces, wherein at least one corridor separates the socket pieces.

2. The socket of claim 1, wherein the plurality of socket pieces are configured to secure a processing unit to a printed circuit board.

3. The socket of claim 1, wherein the at least one corridor is filled with a thermally conductive material.

4. The socket of claim 1, wherein the multiple piece socket includes a load mechanism frame.

5. The socket of claim 1, wherein a power plane is located within a layer of a printed circuit board beneath the at least one corridor.

6. The socket of claim 1, wherein the at least one corridor increases a number of signal traces from the multiple piece socket.

7. The socket of claim 1, wherein the at least one corridor decreases an R-path for a computing device including the multiple piece socket.

8. A socket for an integrated circuit package, comprising:
a plurality of socket pieces, wherein at least one channel separates the socket pieces.

9. The socket of claim 8, wherein the plurality of socket pieces are configured to secure the integrated circuit package to a printed circuit board.

10. The socket of claim 8, wherein the at least one channel is filled with a thermally conductive material that is in contact with the integrated circuit package.

11. The socket of claim 8, wherein the socket includes a load mechanism frame with a lever for securing the integrated circuit package within the socket.

12. The socket of claim 8, wherein a power plane is located within a layer of a printed circuit board beneath the at least one channel.

13. The socket of claim 8, wherein the at least one channel increases a number of signal traces from the multiple piece socket.

14. The socket of claim 8, wherein the at least one channel decreases an R-path for a computing device including the multiple piece socket.

15. The socket of claim 8, wherein the integrated circuit package is coupled with at least one heat sink.

16. A system, comprising:
a host computing system;
a printed circuit board coupled to the host computing system; and
a multiple piece socket coupled to the printed circuit board, wherein the multiple piece socket comprises a plurality of socket pieces and at least one corridor, wherein the at least one corridor separates the socket pieces.

17. The system of claim 16, wherein the plurality of socket pieces are configured to secure a processing unit to a printed circuit board.

18. The system of claim 16, wherein the at least one corridor is filled with a thermally conductive material.

19. The system of claim 16, wherein the at least one corridor decreases an R-path for the system including the multiple piece socket.

20. The system of claim 16, wherein the multiple piece socket includes a load mechanism frame.
